(19) United States
(12) Patent Application Publication
(10) Pub. No.: US 2015/0351217 A1
(43) Pub. Date: Dec. 3, 2015

(54) HEAT DISSIPATION STRUCTURE

(71) Applicant: KANEKA CORPORATION, Osaka (JP)

(72) Inventors: Aki KOUKAMI, Osaka (JP); Kazuo HAGIWARA, Osaka (JP); Keisuke OGUMA, Osaka (JP)

(21) Appl. No.: 14/646,340

(22) PCT Filed: Nov. 20, 2013
(86) PCT No.: PCT/JP2013/081258

§ 371 Date: May 20, 2015

(30) Foreign Application Priority Data
Nov. 21, 2012 (JP) 2012-255644

(51) Int. Cl. H05K 1/02; H05K 9/00

(52) U.S. Cl. CPC H05K 1/0204; H05K 9/0024

(57) ABSTRACT

A heat dissipation structure including: (A) a printed circuit board; (B) a heat-generating element; (C) an electromagnetic shielding case; (D) a rubbery, thermally conductive resin layer with a tensile elastic modulus of 50 MPa or lower and a thermal conductivity of 0.5 W/mK or higher; and (E) a thermally non-conductive layer with a thermal conductivity of lower than 0.5 W/mK, the heat-generating element (B) being placed on the printed circuit board (A), the heat-generating element (B) and the thermally conductive resin layer (D) being in contact with each other, the thermally non-conductive layer (E) being provided between the heat-generating element (B) and the electromagnetic shielding case (C).

### TECHNICAL FIELD

The present invention relates to a heat dissipation structure for use in electronic devices, precision apparatuses, or the like.

### BACKGROUND ART

Electronic devices (e.g. PCs, cellphones, PDAs), lighting and display devices (e.g. LED, EL) and the like have recently made a significant improvement in performance. This improvement is attributed to a significant improvement in the performance of arithmetic elements and light-emitting elements. The improvement in the performance of arithmetic elements and light-emitting elements has been accompanied by a significant increase in the amount of heat generation. This poses the important challenge of how to dissipate heat from such electronic devices, lighting or display devices. In electronic components with a large amount of heat generation, it has been proposed to shield electromagnetic waves entering and leaving the electronic components, in order to avoid superimposition of external electromagnetic waves as noise on input and output signals to and from the electronic components as well as superimposition of electromagnetic waves generated from the electronic components themselves as noise on other signals. Known examples of such an electromagnetic shielding structure include those in which a single or a plurality of electronic components mounted on a printed circuit board are covered from above with a metal case.

However, if the above structure is used, then the electronic components are hermetically closed, and thus are likely to undergo an increase in temperature compared to the other components because the electronic components are surrounded by the air, which is a poor conductor of heat, although the electromagnetic shielding properties are not adversely affected. The electronic components therefore have problems such as that when exposed to a high-temperature atmosphere for a long period of time, they are rapidly deteriorated or less likely to exhibit their properties.

To solve the heat problems in such a system, Patent Literatures 1 and 2 disclose techniques in which a resin is filled into the hermetically closed space formed by a sheet metal case for electromagnetic shielding to dissipate heat generated from electronic components mounted in the case to the outer surface of the case. However, since the thermally conductive resins disclosed are silicone resins, there is a concern regarding contact failures in electronic components due to volatilization of low molecular weight siloxane components or cyclic siloxane components.

Patent Literature 3 describes the use of thermally conductive grease that is placed between a heat-generating element and a heat-dissipating element in an electric or electronic component or the like to dissipate heat from the heat-generating element. However, the electric or electronic component or the like undergoes thermal shrinkage or thermal expansion due to heat from the heat-generating element, which causes variations in the gap distance between the heat-generating element and the heat-dissipating element. When the gap between the heat-generating element and the heat-dissipating element is narrowed, the thermally conductive grease, which is not curable, is pushed out of the gap, whereas a hollow space is formed in the gap when the gap is widened. It is therefore difficult to retain an adequate amount of grease between the heat-generating element and the heat-dissipating element, and thus the heat dissipation properties are not stable.

Patent Literature 4 also describes the use of heat dissipation components such as a heat-dissipating sheet. However, since the surfaces of many of heat-generating elements and heat-dissipating elements for, but not limited to, electric or electronic components are not smooth, heat dissipation components cannot be put in close contact with these heat-generating elements and heat-dissipating elements, and therefore the contact area with the heat-generating elements or heat-dissipating elements is reduced. Similarly, within such an electromagnetic shield as described above, a small heat-generating element and a large heat-generating element are used, and therefore the heat dissipation components such as heat-dissipating sheet cannot conform to the fine irregularities. This reduction in contact area causes a reduction in the efficiency of heat transfer from the heat-generating element to the heat-dissipating element, which does not allow the heat dissipation components to sufficiently exhibit their heat dissipation properties.

Patent Literature 5 discloses a method of applying an epoxy resin as a thermally conductive resin between a device case and a heat-generating element. Epoxy resins, however, are known to generally undergo volumetric shrinkage during the curing reaction so that residual stress or strain occurs in the cured material which can cause defects such as reduced strength and warping deformation of plastic semiconductor packages. Patent Literature 5 also includes a drawing of an example in which the heat-generating element is covered with the epoxy resin so that a space is provided between the epoxy resin and the resin case. This, however, is merely given as an example of a structure having insufficient thermal conductivity. Indeed, Patent Literature 5 insists that if the epoxy resin is not attached to the case, then heat dissipation is insufficient. The thermal conductivity of the epoxy resin in this application is not considered sufficient, and thus it is difficult to dissipate heat sufficiently to the outside. When an epoxy resin is used to efficiently dissipate heat from a heat-generating element to the outside and eliminate heat spots, the epoxy resin usually needs to cover the heat-generating element and further be brought into contact with a resin case or housing to diffuse heat. Consequently, however, the heat from the heat-generating element is conducted even to the housing, which leads to problems such as burn injuries to the user.

### CITATION LIST

### Patent Literature

Patent Literature 1: JP H05-67893 A
Patent Literature 2: JP 2001-251088 A
Patent Literature 3: JP 2000-332169 A
Patent Literature 4: JP 2011-236365 A
Patent Literature 5: JP H03-109393 U

### SUMMARY OF INVENTION

### Technical Problem

An object of the present invention is to solve the heat problems with electronic components placed within an electromagnetic shield on a printed circuit board, by providing a heat dissipation structure formed from a thermally conductive resin composition that does not raise concerns about contact failures in electronic components due to low molecular weight siloxane components or the like, and about leakage from the system during long-term use. Another object of the present invention is to provide a heat dissipation structure which, when used in an electronic device, is capable of preventing users of the electronic device from getting burnt because of the high temperature of the electromagnetic shielding case of the electronic device or the like.

### Solution to Problem

To overcome the above problems, the present invention uses the following solutions.

(1) A heat dissipation structure, including: (A) a printed circuit board; (B) a heat-generating element; (C) an electromagnetic shielding case; (D) a rubbery, thermally conductive resin layer with a tensile elastic modulus of 50 MPa or lower and a thermal conductivity of 0.5 W/mK or higher; and (E) a thermally non-conductive layer with a thermal conductivity of lower than 0.5 W/mK, the heat-generating element (B) being placed on the printed circuit board (A), the heat-generating element (B) and the thermally conductive resin layer (D) being in contact with each other, the thermally non-conductive layer (E) being provided between the heat-generating element (B) and the electromagnetic shielding case (C).

(2) The heat dissipation structure of the item (1), wherein the thermally non-conductive layer (E) is a space layer.

(3) The heat dissipation structure of the item (1) or (2), wherein the thermally conductive resin layer (D) is obtained by curing a thermally conductive resin composition by moisture or heat, wherein the thermally conductive resin composition contains (I) a curable acrylic resin or a curable polypropylene oxide resin and (II) a thermally conductive filler, and has a viscosity of at least 30 Pa·s but not more than 3000 Pa·s and a thermal conductivity of 0.5 W/mK or higher.

### Advantageous Effects of Invention

The heat dissipation structure of the present invention includes a thermally non-conductive layer between an electromagnetic shielding case and a heat-generating element to suppress the increase in the surface temperature of the electromagnetic shielding case. Therefore, the heat dissipation structure is capable of suppressing conduction of heat to the surface of an electronic device including the heat dissipation structure, thereby greatly contributing to prevention of burn injuries to the user of the electronic device.

### BRIEF DESCRIPTION OF DRAWINGS

FIG. 1 is a schematic cross-sectional view illustrating an example of a combination of an electromagnetic shielding case and electronic components on a printed circuit board for use in electronic devices, precision apparatuses or the like.

FIG. 2 is a schematic cross-sectional view according to an example of the present invention.

FIG. 3 is a schematic top view according to examples of the present invention.

FIG. 4 is a schematic cross-sectional view according to another example of the present invention.

FIG. 5 is a schematic cross-sectional view according to yet another example of the present invention.

FIG. 6 is a schematic cross-sectional view according to yet another example of the present invention.

FIG. 7 is a schematic cross-sectional view according to a comparative example of the present invention.

FIG. 8 is a schematic cross-sectional view illustrating an example of a heat dissipation structure of the present invention.

FIG. 9 is a schematic cross-sectional view illustrating another example of a heat dissipation structure of the present invention.

FIG. 10 is a schematic cross-sectional view illustrating yet another example of a heat dissipation structure of the present invention.

FIG. 11 is a schematic cross-sectional view illustrating yet another example of a heat dissipation structure of the present invention.

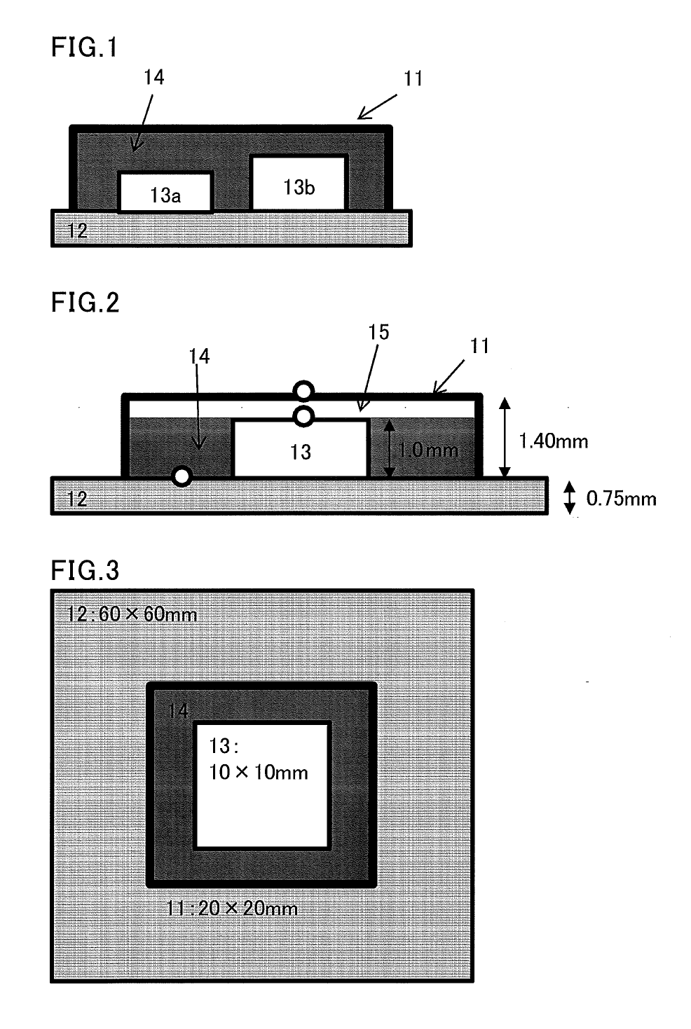

### DESCRIPTION OF EMBODIMENTS

The heat dissipation structure of the present invention includes: (A) a printed circuit board; (B) a heat-generating element; (C) an electromagnetic shielding case; (D) a rubbery, thermally conductive resin layer with a tensile elastic modulus of 50 MPa or lower and a thermal conductivity of 0.5 W/mK or higher; and (E) a thermally non-conductive layer with a thermal conductivity of lower than 0.5 W/mK, the heat-generating element (B) being placed on the printed circuit board (A), the heat-generating element (B) and the thermally conductive resin layer (D) being in contact with each other, the thermally non-conductive layer (E) being provided between the heat-generating element (B) and the electromagnetic shielding case (C).

### <Printed Circuit Board (A)>

The printed circuit board used in the present invention is a component of an electric product on which electronic components for electronic devices or precision apparatuses are fixed and wired. The printed circuit board is not particularly limited as long as it forms an electronic circuit by fixing many electronic components (e.g. integrated circuits, resistors, capacitors) and connecting these components by wiring. Examples include rigid printed circuit boards with inflexible insulating materials, flexible printed circuit boards with thin, flexible materials as insulating substrates, and rigid-flexible printed circuit boards obtained by combining a hard material and a thin, flexible material.

Examples of the material of the printed circuit board include phenolic paper, epoxy paper, glass epoxy, glass fiber epoxy, glass composites, Teflon (registered trademark), ceramics, low temperature co-fired ceramics, polyimides, polyesters, metals, and fluorine.

Nonlimiting examples of the structure of the printed circuit board include single-sided boards with a pattern only on one side, double-sided boards with a pattern on each side, multilayer boards with insulators and patterns combined in a wafer form, and build-up boards in which layers are built up on each other.

The heat dissipation structure of the present invention includes a heat-generating element placed on at least one surface of the printed circuit board, and the surface with the heat-generating element placed thereon may be in contact with the later-described thermally conductive resin layer. Moreover, on the opposite surface of the surface with the heat-generating element placed thereon, wires, heat-generating elements, and electronic components other than heat-generating elements may be placed.

### <Heat-Generating Element (B)>

The heat-generating element used in the present invention may be any electronic component that generates heat when the electronic device or precision apparatus is driven. Examples of the electronic components include semiconductor devices (e.g. transistors, integrated circuits (ICs), CPUs, diodes, LED), electronic tubes, electric motors, resistors, capacitors, coils, relays, piezoelectric elements, oscillators, speakers, heaters, various cells, and various chip components.

The heat-generating element used in the present invention refers to one with a heat density of 0.5 W/cm² or higher. The heat density is preferably 0.7 W/cm² or higher, while it is preferably 1000 W/cm² or lower, and more preferably 800 W/cm² or lower. The heat density refers to thermal energy released per unit area per unit time.

The heat-generating element mounted on the printed circuit board may consist of a single or a plurality of heat-generating elements. Moreover, the heat-generating element may be only placed within the electromagnetic shielding case, or may further be placed outside the electromagnetic shielding case. The heat-generating element mounted on the printed circuit board within the electromagnetic shielding case may also consist of a single or a plurality of heat-generating elements. In the case that a plurality of heat-generating elements are mounted on the printed circuit board within the electromagnetic shielding case, the heights of the heat-generating elements from the printed circuit board are not necessarily the same.

### <Electromagnetic Shielding Case (C)>

The material of the electromagnetic shielding case used in the present invention may be any material that exhibits electromagnetic shielding properties by reflecting, conducting, or absorbing electromagnetic waves. For example, metallic materials, plastic materials, carbon materials, various magnetic materials, and the like can be used, and in particular, metallic materials are suitable.

Suitable metallic materials are those made only of metallic elements. Examples of metallic elements for the metallic materials made of metallic elements include group 1 elements in the periodic table, such as lithium, sodium, potassium, rubidium, and cesium; group 2 elements in the periodic table, such as magnesium, calcium, strontium, and barium; group 3 elements in the periodic table, such as scandium, yttrium, lanthanoids (e.g. lanthanum, cerium), and actinoids (e.g. actinium); group 4 elements in the periodic table, such as titanium, zirconium, and hafnium; group 5 elements in the periodic table, such as vanadium, niobium, and tantalum; group 6 elements in the periodic table, such as chromium, molybdenum, and tungsten; group 7 elements in the periodic table, such as manganese, technetium, and rhenium; group 8 elements in the periodic table, such as iron, ruthenium, and osmium; group 9 elements in the periodic table, such as cobalt, rhodium, and iridium; group 10 elements in the periodic table, such as nickel, palladium, and platinum; group 11 elements in the periodic table, such as copper, silver, and gold; group 12 elements in the periodic table, such as zinc, cadmium, and mercury; group 13 elements in the periodic table, such as aluminum, gallium, indium, and thallium; group 14 elements in the periodic table, such as tin and lead; and group 15 elements in the periodic table, such as antimony and bismuth.

Also, examples of alloys include stainless steel, copper-nickel alloys, brass, nickel-chromium alloys, iron-nickel alloys, zinc-nickel alloys, gold-copper alloys, tin-lead alloys, silver-tin-lead alloys, nickel-chromium-iron alloys, copper-manganese-nickel alloys, and nickel-manganese-iron alloys.

Examples of various metallic compounds containing nonmetallic elements together with metallic elements are not particularly limited, provided that they contain the aforementioned metallic elements or alloys and can exhibit electromagnetic shielding properties. For example, metallic sulfides (e.g. copper sulfide); and metallic oxides and metallic complex oxides (e.g. iron oxide, titanium oxide, tin oxide, indium oxide, cadmium-tin oxide), and the like may be used.

Suitable among the metallic materials are gold, silver, aluminum, iron, copper, nickel, stainless steel, and copper-nickel alloys.

Examples of the plastic materials include conductive plastics such as polyacethylene, polypyrrole, polyacene, polyphenylene, polyaniline, and polythiophene.

Moreover, carbon materials such as graphite may be used.

Examples of the magnetic materials include soft magnetic powder, various ferrites, and zinc oxide whiskers. Suitable magnetic materials are ferromagnetic materials with ferromagnetism or ferrimagnetism. Specific examples include ferrites with high magnetic permeability, pure iron, silicon-containing iron, nickel-iron alloys, iron-cobalt alloys, amorphous metal materials with high magnetic permeability, iron-aluminum-silicon alloys, iron-aluminum-silicon-nickel alloys, and iron-chromium-cobalt alloys.

The structure of the electromagnetic shielding case may be any structure capable of exhibiting electromagnetic shielding properties. Typically, the electromagnetic shielding case is placed on the ground layer on the board as illustrated in FIG. 2, and covers electronic components that will generate electromagnetic waves. The electromagnetic shielding case and the ground layer on the board are typically bonded to each other with solder or a conductive material, for example. The electromagnetic shielding case may have holes or apertures as long as they do not deteriorate the electromagnetic shielding properties. Also, the electromagnetic shielding case is not necessarily an integrated product, and may have an upper portion separable like a lid or may be separable into two or more portions.

The electromagnetic shielding case preferably has a thermal conductivity as high as possible because higher thermal conductivity provides more uniform temperature distribution and more effective conduction of heat from the heat-generating element within the electromagnetic shielding case to the outside. For enhanced heat dissipation, the thermal conductivity of the electromagnetic shielding case is preferably 1 W/mK or higher, more preferably 3 W/mK or higher, still more preferably 5 W/mK or higher, and most preferably 10 W/mK or higher. The thermal conductivity of the electromagnetic shielding case is preferably 10000 W/mK or lower.

### <Thermally Conductive Resin Layer (D)>

The thermally conductive resin layer used in the present invention is a rubbery resin layer with a thermal conductivity of 0.5 W/mK or higher and a tensile elastic modulus of 50 MPa or lower. The thermal conductivity of the thermally conductive resin layer is preferably 0.7 W/mK or higher, and more preferably 0.8 W/mK or higher. Since the thermal conductivity is 0.5 W/mK or higher, the heat from the heat-generating element can be effectively dissipated, which consequently leads to an improvement in the performance of electronic devices. A thermal conductivity of lower than 0.5 W/mK may not allow for suitable heat dissipation, thereby resulting in various problems including deterioration in the performance of electronic components around the heat-generating element and a reduction in the life of the components.

The thermal conductivity values herein are measured at 23° C. Moreover, the thermal conductivity of the thermally conductive resin layer is almost the same as the thermal conductivity of the thermally conductive resin composition.

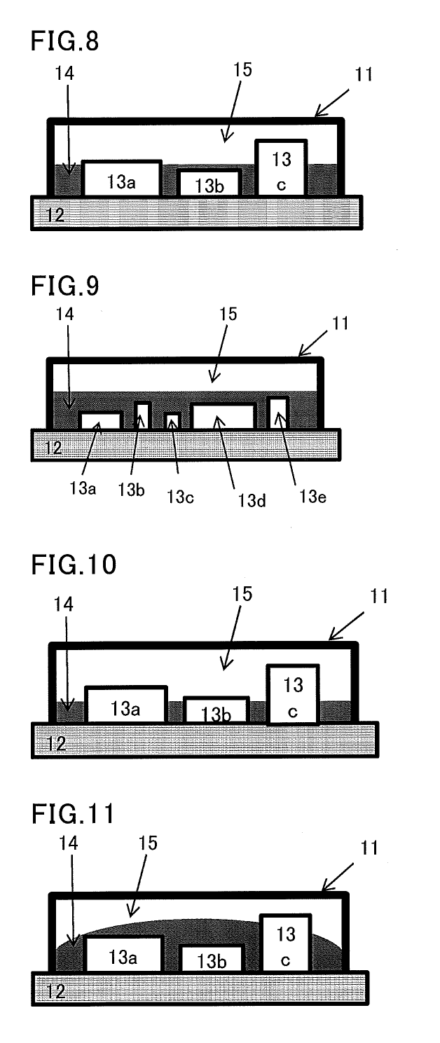

The thermally conductive resin layer is in contact with the heat-generating element, and in particular the heat-generating element within the electromagnetic shielding case. The heat-generating element may be completely covered with the thermally conductive resin layer, or may be partially exposed. In the case that a plurality of heat-generating elements are placed within the electromagnetic shielding case, all of the heat-generating elements may be completely covered with the thermally conductive resin layer as illustrated in FIG. 9, or some of the heat-generating elements may be exposed as illustrated in FIG. 8 and FIG. 11, or all of the heat-generating elements may be exposed as illustrated in FIG. 10. In the portion where the thermally conductive resin layer and the heat-generating element are in contact with each other, the thermally conductive resin layer and the heat-generating element are preferably in close contact with each other because the contact area is increased to achieve good heat dissipation. Multiple thermally conductive resin layers differing in material or thermal conductivity may be provided.

The heat dissipation structure of the present invention including the thermally conductive resin layer within the electromagnetic shielding case can conduct heat from the electronic components to the electromagnetic shielding case and the board, thereby reducing heat generation from the electronic components and greatly contributing to prevention of deterioration in the performance of the electronic components.

The thermally conductive resin layer may further be in contact with the printed circuit board. This is because the heat from the heat-generating element can be dissipated also into the printed circuit board, whereby the increase in the temperature of the electromagnetic shielding case can be suppressed.

The thermally conductive resin layer may be in contact with the ceiling wall (portion facing the printed circuit board) of the electromagnetic shielding case. The contact area is preferably as small as possible, and more preferably zero. This is because the ceiling wall of the electromagnetic shielding case usually has the largest area among the wall portions of the electromagnetic shielding case, and therefore if heat is conducted to this portion via the thermally conductive resin layer to increase the temperature, the user may get burnt.

The thermally conductive resin layer may be in contact with the side wall (portion other than the ceiling wall) of the electromagnetic shielding case.

Tensile elastic modulus as used herein is measured in accordance with JIS K 6251.

The tensile elastic modulus of the thermally conductive resin layer is 50 MPa or lower, and preferably 30 MPa or lower. When the board is subjected to expansion or shrinkage or to compression or deformation by external pressure, the layer with a tensile elastic modulus of higher than 50 MPa cannot follow these movements, unfortunately resulting in cracks in the resin or damage to the components.

Since the thermally conductive resin layer has a low tensile elastic modulus, residual strain hardly occurs in the material applied, and therefore only very small stress is applied to the board and heat-generating element.

Examples of the resin forming the thermally conductive resin layer with a tensile elastic modulus of 50 MPa or lower include curable acrylic or methacrylic resins; curable polyether resins, typically curable polypropylene oxide resins; and curable polyolefin resins, typically curable polyisobutylene resins, as described later.

The thermally conductive resin layer may have any shape, e.g., a sheet-like, tape-like, strip-like, disc-like, circular, block-like, or irregular shapes.

### <Thermally Conductive Resin Composition>

The thermally conductive resin layer in the present invention is preferably a cured product of a thermally conductive resin composition.

When the thermally conductive resin layer is obtained by filling the electromagnetic shielding case with an uncured thermally conductive resin composition and then curing the composition, the layer can be in close contact with the heat-generating elements even when the elements have different heights, and thus can efficiently conduct heat from the heat-generating elements to the electromagnetic shielding case and the printed circuit board.

The thermally conductive resin composition is preferably curable by moisture or heat.

The thermally conductive resin composition may be a composition at least containing a curable resin (I) and a thermally conductive filler (II). The composition may optionally contain, in addition to these components, curing catalysts for curing the curable resin, anti-heat aging agents, plasticizers, extenders, thixotropy imparting agents, storage stabilizers, dehydrating agents, coupling agents, ultraviolet absorbers, flame retardants, electromagnetic wave absorbents, fillers, and solvents.

The thermally conductive resin composition preferably has a viscosity of 30 Pa·s or higher before curing, and is also preferably a resin composition that is fluid but relatively highly viscous. The viscosity before curing is measured at 23° C. and 50% RH with a BH viscometer at 2 rpm. The viscosity before curing is more preferably 40 Pa·s or higher, and still more preferably 50 Pa·s or higher. The upper limit of the viscosity is not particularly limited, but is preferably 5000 Pa·s or lower, more preferably 4000 Pa·s or lower, and still more preferably 3000 Pa·s or lower. A viscosity before curing of lower than 30 Pa·s may cause the problem of reduced workability, such as leakage after application. A viscosity before curing of higher than 5000 Pa·s may cause difficulty in application, or may cause air to be trapped during application, which can reduce thermal conductivity.

The thermal conductivity of the thermally conductive resin composition is preferably 0.5 W/mK or higher, more preferably 0.7 W/mK or higher, and still more preferably 0.8 W/mK or higher.

### <Curable Resin (I)>

The curable resin is preferably a curable liquid resin that has a reactive group in the molecule. Specific examples of the resin include curable vinyl resins, typically curable acrylic or methacrylic resins; curable polyether resins, typically curable polypropylene oxide resins; and curable polyolefin resins, typically curable polyisobutylene resins.

When the thermally conductive resin layer is a cured product of a liquid thermally conductive resin composition, the composition can not only fill the electromagnetic shielding case without hollow space, but also, when cured, has no risk of leakage from the system with time.

Examples of reactive groups include various reactive functional groups such as an epoxy group, a hydrolyzable silyl group, a vinyl group, an acryloyl group, a SiH group, a urethane group, a carbodiimide group, and a combination of a carboxylic anhydride group and an amino group.

In the case that the curable resin is cured via a combination of two types of reactive groups or by a reaction between the reactive group and a curing catalyst, the curable resin may be prepared into a two-pack type composition, which can then be curable by mixing the two components before application to the board or heat-generating element. The curable resin containing a hydrolyzable silyl group, which is curable by a reaction with moisture in the air, may be prepared into a one-pack type room temperature-curable composition. In the case of using, for example, a combination of a vinyl group, a SiH group, and a Pt catalyst, or a combination of a radical initiator and an acryloyl group, the curable resin may be prepared into a one-pack type or two-pack type curable composition, which can then be cured by heating to the crosslinking temperature or by applying crosslinking energy such as ultraviolet light or electron beams. In general, if the entire heat dissipation structure can be easily heated to a certain degree, it is preferred to use a heat-curable composition, while if the heat dissipation structure cannot be easily heated, it is preferred to prepare a two-pack type curable composition or a moisture-curable composition, although the present invention is not limited thereto.

In particular, the curable resin is preferably a curable acrylic resin or a curable polypropylene oxide resin because then, for example, the problem of contamination inside the electronic device by low molecular weight siloxanes is less likely to occur and because they have excellent heat resistance. Examples of curable acrylic resins include various known reactive acrylic resins. Preferred among these are acrylic oligomers having a reactive group at a molecular end. Such a curable acrylic resin is most preferably a curable acrylic resin produced by living radical polymerization, and particularly by atom transfer radical polymerization, in combination with a curing catalyst. Kaneka XMAP available from Kaneka Corporation is a known example of such a resin. Moreover, examples of curable polypropylene oxide resins include various known reactive polypropylene oxide resins, such as Kaneka MS polymer available from Kaneka Corporation. These curable resins may be used alone or in combination of two or more. The combined use of two or more types of curable resins can be expected to enhance the elasticity and peelability of the cured product.

### <Thermally Conductive Filler (II)>

From various standpoints such as thermal conductivity, availability, ability to provide electrical characteristics (e.g. insulation properties, electromagnetic wave absorption properties), filling properties, and toxicity, preferred examples of the thermally conductive filler include carbon compounds such as graphite and diamond; metal oxides such as aluminum oxide, magnesium oxide, beryllium oxide, titanium oxide, zirconium oxide, and zinc oxide; metal nitrides such as boron nitride, aluminum nitride, and silicon nitride; metal carbides such as boron carbide, aluminum carbide, and silicon carbide; metal hydroxides such as aluminum hydroxide and magnesium hydroxide; metal carbonates such as magnesium carbonate and calcium carbonate; crystalline silica; fired products of organic polymers, such as fired products of acrylonitrile polymers, fired products of furan resin, fired products of cresol resin, fired products of polyvinyl chloride, fired products of sugar, and fired products of charcoal; complex ferrites of Zn; Fe—Al—Si ternary alloys; and metal powder.

For improved dispersibility in resin, such a thermally conductive filler is preferably surface-treated by, for example, a silane coupling agent (e.g. vinylsilane, epoxysilane, (meth)acrylsilane, isocyanatosilane, chlorosilane, aminosilane) or a titanate coupling agent (e.g. alkoxy titanate, amino titanate), a fatty acid (e.g. a saturated fatty acid such as caproic acid, caprylic acid, capric acid, lauric acid, myristic acid, palmitic acid, stearic acid, and behenic acid; an unsaturated fatty acid such as sorbic acid, elaidic acid, oleic acid, linoleic acid, linolenic acid, and erucic acid), or a resin acid (e.g. abietic acid, pimaric acid, levopimaric acid, neoabietic acid, palustric acid, dehydroabietic acid, isopimaric acid, sandaracopimaric acid, communic acid, secodehydroabietic acid, dihydroabietic acid).

The amount of such a thermally conductive filler used is preferably 25 vol % or more of the total composition in terms of volume ratio (%) in order to increase the thermal conductivity of the cured product of the thermally conductive resin composition. An amount of less than 25 vol % tends to result in insufficient thermal conductivity. If higher thermal conductivity is desired, the amount of the thermally conductive filler used is more preferably 30 vol % or more, still more preferably 40 vol % or more, and particularly preferably 50 vol % or more of the total composition. The volume ratio (%) of the thermally conductive filler is also preferably 90 vol % or less of the total composition. An amount of more than 90 vol % may excessively increase the viscosity of the thermally conductive resin composition before curing.

As used herein, the volume ratio (%) of the thermally conductive filler is calculated from the weight fractions and the specific gravities of the resin component and the thermally conductive filler using the equation below. Please note that the thermally conductive filler is simply described as “filler” in the following equation.

Filler volume ratio (vol %)=(filler weight fraction/filler specific gravity)/[(resin component weight fraction/resin component specific gravity)+(filler weight fraction/filler specific gravity)]×100

Herein, the resin component refers to all the components except the thermally conductive filler.

One suitable way of increasing the filling ratio of the thermally conductive filler relative to the resin is to use a combination of at least two types of thermally conductive fillers with different particle sizes. In this case, it is preferred that the particle size of the thermally conductive filler with a larger particle size is more than 10 μm, while the particle size of the thermally conductive filler with a smaller particle size is 10 μm or less.

For example, high thermal conductivity can be achieved by the use of hexagonal boron nitride as the filler with a high thermal conductivity and a smaller particle size in combination with a spherical thermally conductive filler as the thermally conductive filler with a larger particle size. In this case, for example, the particle size of hexagonal boron nitride fine particles is preferably at least 10 μm but less than 60 μm, and more preferably at least 10 μm but less than 50 μm, while the particle size of spherical thermally conductive filler with a smaller particle size is preferably at least 1 μm but less than 20 μm, and more preferably at least 2 μm but less than 10 μm. The volume ratio of hexagonal boron nitride fine particles to spherical thermally conductive filler is also preferably 10:90 to 50:50. As the amount of hexagonal boron nitride fine particles relative to the spherical thermally conductive filler increases, the viscosity ratio increases, resulting in good workability.

The thermally conductive filler may be a single thermally conductive filler or may also be a combination of two or more different thermally conductive fillers.

### <Thermally Non-Conductive Layer (E)>

The thermally non-conductive layer used in the present invention has a thermal conductivity of lower than 0.5 W/mK, and thus is less likely to conduct heat to the surroundings because of the low thermal conductivity. The thermal conductivity is preferably lower than 0.4 W/mK, and more preferably lower than 0.3 W/mK.

The thermal conductivity values are measured at 23° C.

The thermally non-conductive layer may be any layer having a thermal conductivity of lower than 0.5 W/mK, such as, for example, a resin layer, a layer of infill material other than resin, or a space layer (e.g. gas layer such as air, vacuum layer). The layer may also be in any state, such as a gas, liquid, solid, or vacuum.

Examples of the thermally non-conductive layer include air, gaskets, and foams. In particular, the layer is preferably a space layer because additional steps or materials are not required.

The thermally non-conductive layer is provided at least in a portion of the space defined by the heat-generating element and the electromagnetic shielding case. The thermally non-conductive layer only needs to be located in the space between the heat-generating element and the electromagnetic shielding case in order to block the flow of heat from the heat-generating element, and another component such as the thermally conductive resin layer may further be located between the thermally non-conductive layer and the heat-generating element.

Multiple different thermally non-conductive layers may be provided.

The thermally non-conductive layer is preferably in contact with the ceiling wall of the electromagnetic shielding case, and more preferably in contact with the entire surface of the ceiling wall. This is for the purpose of blocking heat from the heat-generating element to suppress the increase in the temperature of the ceiling wall.

The thickness of the thermally non-conductive layer is preferably 0.05 mm or more, and more preferably 0.1 mm or more.

### <Heat Dissipation Structure>

The heat dissipation structure of the present invention includes (A) the printed circuit board, (B) the heat-generating element, (C) the electromagnetic shielding case, (D) the rubbery, thermally conductive resin layer, and (E) the thermally non-conductive layer. A specific structure is an electronic device including electronic component(s) located on the printed circuit board and covered with the electromagnetic shielding case filled with the cured thermally conductive resin. The use of the electronic device is not particularly limited, provided that the electronic device includes these components.

In the heat dissipation structure of the present invention, the volume of the space defined by the printed circuit board and the electromagnetic shielding case is preferably 0.05 mm³ or more, and more preferably 0.08 mm³ or more. Moreover, the upper limit is preferably 30000 mm³ or less, and more preferably 20000 mm³ or less.

In the heat dissipation structure of the present invention, the heat from the heat-generating element is preferably mostly flown in the direction of the printed circuit board and then dissipated to the surroundings of the structure. In order to dissipate heat to the surroundings of the structure, a heat-dissipating element (i.e. a component capable of dissipating heat) may be placed on the surface of the printed circuit board opposite to the surface where the heat-generating element is placed, as illustrated in FIG. 6. Examples of the heat-dissipating element include heat sinks, metal plates, and heat-dissipating plates. The heat-dissipating element may also be the above-described cured product of the thermally conductive resin composition. The heat-dissipating element may further be connected to another heat-dissipating element.

### <Electronic Devices and Precision Apparatuses>

Electronic devices and precision apparatuses can be manufactured using the heat dissipation structure of the present invention. The electronic devices and precision apparatuses are not particularly limited as long as they internally include electronic components located on the board and covered with the electromagnetic shielding case. Examples include devices such as servers, server computers, and desktop computers, gaming machines, portable devices such as laptops, electronic dictionaries, PDAs, cellphones, smartphones, tablet PCs, and portable music players, display devices such as liquid crystal displays, plasma displays, surface-conduction electron-emitter displays (SEDs), LED, organic EL, inorganic EL, liquid crystal projectors, and clocks and watches, image forming devices such as ink jet printers (ink heads) and electrophotographic devices (developing devices, fixing devices, heat rollers, heat belts), semiconductor-related parts such as semiconductor devices, semiconductor packages, semiconductor encapsulation cases, semiconductor die bonding devices, CPUs, memories, power transistors, and power transistor cases, wiring boards such as rigid wiring boards, flexible wiring boards, ceramic wiring boards, build-up wiring boards, and multi-layer board (these wiring boards also include printed wiring boards and the like), manufacturing equipment such as vacuum processing devices, semiconductor manufacturing equipment, and display device manufacturing equipment, thermal insulation systems such as insulating materials, vacuum insulating materials, and radiation insulating materials, data recording devices such as DVDs (optical pickups, laser generation devices, laser receiving devices) and hard disk drives, image recording devices such as cameras, video cameras, digital cameras, digital video cameras, microscopes, and CCDs, and battery equipment such as battery chargers, lithium-ion cells, fuel cells, and solar cells.

### EXAMPLES

The embodiments and effects of the present invention will be explained below by way of examples which, however, are not intended to limit the scope of the present invention.

### <Evaluation>

### (Viscosity of Thermally Conductive Resin Composition)

The viscosity of the thermally conductive resin compositions was measured at 23° C. and 50% RH with a BH viscometer at 2 rpm.

### (Thermal Conductivity of Thermally Conductive Resin Composition)

The thermally conductive curable resin compositions were wrapped in Saran Wrap (registered trademark) and then measured for thermal conductivity at 23° C. using a hot disk thermal conductivity meter (TPA-501 available from Kyoto Electronics Manufacturing Co., Ltd.) by sandwiching a sensor (size: 4φ) between two specimens.

### (Tensile Elastic Modulus of Cured Product of Thermally Conductive Resin Composition)

The tensile elastic modulus of mini dumbbell specimens prepared by curing the thermally conductive resin compositions at 23° C. and 50% RH was measured in accordance with JIS K 6251.

### (Measurement of Temperatures of Electronic Component, Board, and Electromagnetic Shielding Case)

The simple models illustrated in FIGS. 2 to 7 were prepared, and the temperatures of the electronic component, board, and electromagnetic shielding case of each model were measured with a Teflon (registered trademark)-insulated ultrafine duplex thermocouple wire (TT-D-40-SLE available from OMEGA Engineering Inc.). The temperature values were measured after the electronic component models were allowed to generate heat for one hour.

In the models of FIGS. 2 and 4 to 7, a heat-generating element 13 and an electromagnetic shielding case 11 were placed in the center of a board 12 as illustrated in FIG. 3. The thermocouples were mounted in the center of the upper surfaces of the heat-generating element and the electromagnetic shielding case and at a middle point (on the board) between the side surfaces of the heat-generating element and the electromagnetic shielding case.

11: Electromagnetic shielding case: SUS (thickness: 0.3 mm), 20 mm×20 mm×1.40 mm
12: Board: made of glass epoxy, 60 mm×60 mm×0.75 mm
13: Electronic component (heat-generating element): alumina heat-generating element (heat generation: 1 W, heat density: 1 W/cm²), 10 mm×10 mm×1.05 mm
14: Thermally conductive resin composition (or cured product)
Symbol O: Thermocouple mounting position
(Leakage of Resin from Electromagnetic Shielding Case)

After the electromagnetic shielding case was filled with the thermally conductive resin composition, leakage of the composition from the system was visually evaluated.

### (Synthesis 1)

In a nitrogen atmosphere, a 250-L reactor was charged with CuBr (1.09 kg), acetonitrile (11.4 kg), butyl acrylate (26.0 kg), and diethyl 2,5-dibromoadipate (2.28 kg), and the mixture was stirred at 70° C. to 80° C. for about 30 minutes. Then, pentamethyldiethylenetriamine was added to the mixture and a reaction was started. After 30 minutes from the start of the reaction, butyl acrylate (104 kg) was continuously added to the mixture over two hours. During the reaction, pentamethyldiethylenetriamine was added as needed so that the internal temperature was maintained at 70° C. to 90° C. The total amount of pentamethyldiethylenetriamine used up to this point was 220 g. After four hours from the start of the reaction, the mixture was heated with stirring under reduced pressure at 80° C. to remove volatile matter. Thereto were added acetonitrile (45.7 kg), 1,7-octadiene (14.0 kg), and pentamethyldiethylenetriamine (439 g), and the mixture was continuously stirred for 8 hours. The mixture was heated with stirring under reduced pressure at 80° C. to remove volatile matter.

To the resulting concentrate was added toluene to dissolve the polymer therein, followed by adding diatomaceous earth as a filtering aid and aluminum silicate and hydrotalcite as adsorbents. The mixture was then heated with stirring in an oxygen-nitrogen mixed gas atmosphere (oxygen concentration: 6%) at an internal temperature of 100° C. The solids in the mixture were removed by filtering, and the filtrate was heated with stirring under reduced pressure at an internal temperature of 100° C. to remove volatile matter.

To the resulting concentrate were further added aluminum silicate and hydrotalcite as adsorbents and an anti-heat aging agent, and the mixture was heated with stirring under reduced pressure (average temperature: about 175° C.; degree of vacuum: 10 Torr or lower).

Further, aluminum silicate and hydrotalcite were added as adsorbents and an antioxidant was also added. Then, the resulting mixture was heated with stirring in an oxygen-nitrogen mixed gas atmosphere (oxygen concentration: 6%) at an internal temperature of 150° C.

To the resulting concentrate was added toluene to dissolve the polymer therein. Then the solids in the mixture were removed by filtering, and the filtrate was heated with stirring under reduced pressure to remove volatile matter. Thus, a polymer containing an alkenyl group was obtained.

The polymer containing an alkenyl group, dimethoxymethylsilane (2.0 molar equivalents to the alkenyl group), methyl orthoformate (1.0 molar equivalent to the alkenyl group), a platinum catalyst (a xylene solution of bis(1,3-divinyl-1,1,3,3-tetramethyldisiloxane)-platinum complex catalyst; hereinafter referred to as platinum catalyst) (10 mg calculated as platinum per kilogram of polymer) were mixed, and the mixture was heated with stirring at 100° C. in a nitrogen atmosphere. After confirming the disappearance of the alkenyl group, the reaction mixture was concentrated to provide a poly(n-butyl acrylate) resin (I−1) having a dimethoxysilyl group at an end. The obtained resin had a number average molecular weight of about 26,000 and a molecular weight distribution of 1.3. The average number of silyl groups introduced per molecule of resin was about 1.8 as determined by ¹H NMR analysis.

### (Synthesis 2)

Using polyoxypropylenediol with a number average molecular weight of about 2,000 as an initiator, propylene oxide was polymerized in the presence of a zinc hexacyanocobaltate-glyme complex catalyst to obtain a polypropylene oxide having a number average molecular weight of 25,500 (as measured using a solvent delivery system (HLC-8120 GPC available from Tosoh Corporation), a column (TSK-GEL H type available from Tosoh Corporation), and a solvent (THF) calibrated with polystyrene standards). Subsequently, 1.2 equivalents of NaOMe in methanol was added to the hydroxy groups of the hydroxy-terminated polypropylene oxide and the methanol was distilled off. Then, the terminal hydroxy groups were converted into allyl groups by adding allyl chloride. Unreacted allyl chloride was removed under reduced pressure. Then 100 parts by weight of the resulting crude allyl-terminated polypropylene oxide was combined with 300 parts by weight of n-hexane and 300 parts by weight of water. After stirring, the water was removed from the mixture by centrifugation. The resulting hexane solution was further combined with 300 parts by weight of water, followed by stirring. After the water was removed again by centrifugation, the hexane was removed under reduced pressure. Thus, an allyl-terminated bifunctional polypropylene oxide having a number average molecular weight of about 25,500 was obtained.

Then 100 parts by weight of the obtained allyl-terminated polypropylene oxide was reacted with 0.95 parts by weight of trimethyoxysilane at 90° C. for five hours in the presence of 150 ppm of an isopropanol solution of platinum-vinylsiloxane complex (platinum content: 3 wt %) as a catalyst. Thus, a trimethoxysilyl-terminated polyoxypropylene polymer (I-2) was obtained. The average number of terminal trimethoxysilyl groups per molecule was 1.3 as determined by ¹H NMR in the same manner as above.

### Examples 1 and 2

The resin (I-1) obtained in Synthesis 1 (90 parts by weight), the resin (I-2) obtained in Synthesis 2 (10 parts by weight), a plasticizer (Monocizer W-7010 available from DIC; 100 parts by weight), an antioxidant (Irganox 1010; 1 part by weight), and thermally conductive fillers shown in Table 1 were sufficiently stirred and kneaded by hand. Then the mixture was dehydrated in vacuo while being kneaded under heat with a 5-L butterfly mixer. After completion of the dehydration, the mixture was cooled and mixed with a dehydrating agent (A171; 2 parts by weight) and curing catalysts (tin neodecanoate and neodecanoic acid; 4 parts by weight each). Thus, a thermally conductive curable resin composition was obtained. After the obtained thermally conductive composition was measured for viscosity and thermal conductivity, the thermally conductive resin composition was filled as shown in the simple model of FIG. 2, and cured to prepare a heat dissipation structure. Then, the temperatures and the occurrence of leakage of the resin composition from the electromagnetic shielding case were evaluated. Table 1 shows the results.

### Example 3

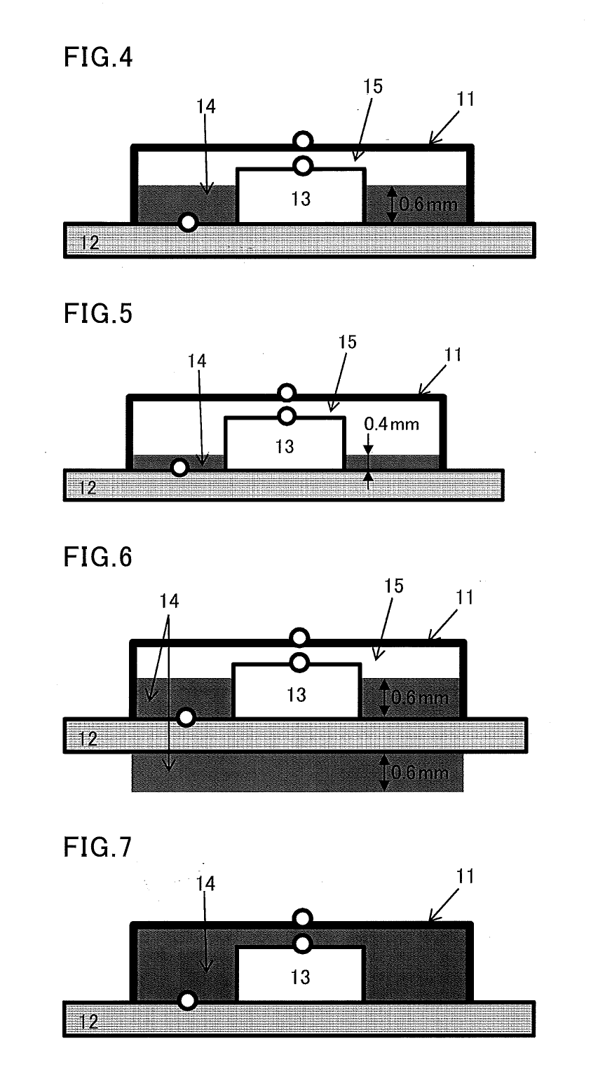

A heat dissipation structure (thickness of thermally conductive resin layer: 0.6 mm) was prepared and evaluated as in Examples 1 and 2, except that the thermally conductive resin composition was filled as shown in the simple model of FIG. 4. Table 1 shows the evaluation results.

### Example 4

A heat dissipation structure (thickness of thermally conductive resin layer: 0.4 mm) was prepared and evaluated as in Examples 1 and 2, except that the thermally conductive resin composition was filled as shown in the simple model of FIG. 5. Table 1 shows the evaluation results.

### Example 5

The thermally conductive resin composition was filled as shown in the simple model of FIG. 6, and a heat-dissipating element (20 mm×20 mm×0.6 mm) was also formed from the thermally conductive resin composition on the reverse side of the board (where the heat-generating element was not placed). A heat dissipation structure (thickness of thermally conductive resin layer: 0.6 mm) was prepared and evaluated as in Examples 1 and 2. Table 1 shows the evaluation results.

### Comparative Example 1

A heat dissipation structure was prepared and evaluated as in Examples 1 and 2, but using no thermally conductive resin composition. Table 1 shows the evaluation results.

### Comparative Example 2

A heat dissipation structure was prepared and evaluated as in Examples 1 and 2, except that the thermally conductive resin composition was filled as shown in the simple model of FIG. 7. Table 1 shows the evaluation results.

### Comparative Example 3

A resin composition containing no thermally conductive filler was prepared. After the composition was measured for viscosity and thermal conductivity, it was filled as shown in the simple model of FIG. 2, and a heat dissipation structure was prepared and evaluated as in Examples 1 and 2. Table 1 shows the evaluation results.

TABLE 1

| | | | | | | | | Com- | Com- | Com- |
|---|---|---|---|---|---|---|---|---|---|---|
| | | | | | | | | parative | parative | parative |
| | | | Example 1 | Example 2 | Example 3 | Example 4 | Example 5 | Example 1 | Example 2 | Example 3 |
| Thermally | Aluminum hydroxide | phr | 250 | 450 | 450 | 450 | 450 | — | 450 | — |
| conductive filler | Zinc oxide | phr | 50 | 100 | 100 | 100 | 100 | — | 100 | — |
| Viscosity of thermally conductive | | Pa · s | 150 | 300 | 300 | 300 | 300 | — | 300 | 13 |
| resin composition | | | | | | | | | | |
| Thermal conductivity of thermally | | W/(m · K) | 0.5 | 1.0 | 1.0 | 1.0 | 1.0 | — | 1.0 | 0.2 |
| conductive resin composition | | | | | | | | | | |
| Tensile elastic modulus of cured | | MPa | 3.5 | 4.0 | 4.0 | 4.0 | 4.0 | — | 4.0 | 10.0 |
| product | | | | | | | | | | |
| Filling | | | Filled | Filled | Filled | Filled | Filled | Not filled | Filled | Filled |
| Filled portion | | | FIG. 2 | FIG. 2 | FIG. 4 | FIG. 5 | FIG. 6 | N/A | FIG. 7 | FIG. 2 |
| Leakage of composition from system | | | Not | Not | Not | Not | Not | Not | Not | Observed |
| | | | observed | observed | observed | observed | observed | observed | observed | |
| Temperature | Electromagnetic | ° C. | 81.4 | 79.8 | 80.3 | 81.7 | 76.5 | 83.8 | 87 | 85.3 |
| measurement | shiedling case | | | | | | | | | |
| | Electronic component | ° C. | 108.5 | 98.4 | 103.7 | 109.5 | 92 | 115.8 | 85 | 112.2 |
| | Printed circuit board | ° C. | 72.3 | 74.5 | 74.8 | 73.9 | 73.2 | 71.5 | 74 | 68.1 |

Table 1 shows that in Examples 1 to 5, the temperature of the electromagnetic shielding case and the temperature of the heat-generating element were greatly reduced and the temperature of the board was increased, as compared to Comparative Example 1. This indicates that the heat from the heat-generating element was conducted to the printed circuit board by the thermally conductive resin layer. It was demonstrated that provision of the thermally conductive resin layer within the electromagnetic shielding case allows for efficient dissipation of heat from the electromagnetic shielding case.

Moreover, comparison between Comparative Example 2 and Examples 1 to 5 shows that the temperature of the electromagnetic shielding case was greatly reduced in Examples 1 to 5. This was achieved by provision of a space between the upper surface (ceiling wall) of the electromagnetic shielding case and the heat-generating element. Furthermore, the provision of the thermally conductive resin layer on the reverse side of the printed circuit board was found to suitably reduce the temperatures of the upper surface of the electromagnetic shielding case and the electronic component (Example 5). Suppressing the increase in the temperature of the upper surface of the electromagnetic shielding case leads to suppression of the increase in the temperature of the surface of the electronic device, which greatly contributes to prevention of accidents such as burn injuries to the user.

In Comparative Example 3 in which the thermal conductivities of the resin composition and the cured product thereof were low, it was not only found that the above effect was small but also that leakage of the resin composition from the electromagnetic shielding case occurred because of the low viscosity of the composition.

### REFERENCE SIGNS LIST

11 Electromagnetic shielding case
12 Printed circuit board
13, 13a, 13b, 13c, 13d, 13e Heat-generating element
14 Thermally conductive resin composition (or cured product thereof)
15 Thermally non-conductive layer

1. A heat dissipation structure, comprising:
(A) a printed circuit board;
(B) a heat-generating element;
(C) an electromagnetic shielding case;
(D) a rubbery, thermally conductive resin layer with a tensile elastic modulus of 50 MPa or lower and a thermal conductivity of 0.5 W/mK or higher; and
(E) a thermally non-conductive layer with a thermal conductivity of lower than 0.5 W/mK,
the heat-generating element (B) being placed on the printed circuit board (A),
the heat-generating element (B) and the thermally conductive resin layer (D) being in contact with each other,
the thermally non-conductive layer (E) being provided between the heat-generating element (B) and the electromagnetic shielding case (C).

2. The heat dissipation structure according to claim 1,
wherein the thermally non-conductive layer (E) is a space layer.

3. The heat dissipation structure according to claim 1,
wherein the thermally conductive resin layer (D) is obtained by curing a thermally conductive resin composition by moisture or heat, wherein the thermally conductive resin composition comprises (I) a curable acrylic resin or a curable polypropylene oxide resin and (II) a thermally conductive filler, and has a viscosity of at least 30 Pa·s but not more than 3000 Pa·s and a thermal conductivity of 0.5 W/mK or higher.
